(19) United States
(12) Patent Application Publication
(10) Pub. No.: US 2008/0315890 A1
(43) Pub. Date: Dec. 25, 2008

(54) Image Display Device

(76) Inventors: Naruhiko KASAI, Yokohama (JP); Yasuyuki Kudo, Fujisawa (JP); Yukari Katayama, Chigasaki (JP); Hajime Akimoto, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/139,577

(22) Filed: Jun. 16, 2008

(30) Foreign Application Priority Data
Jun. 20, 2007 (JP) 2007-162585

(51) Int. Cl. G01R 31/08

(52) U.S. Cl. 324/523

(57) ABSTRACT

An image display device includes a black spot defect position determination circuit which determines a position of a black-spot defective pixel of a self-luminous display panel. A detection-use current source in the black spot defect position determination circuit is connected to pixels during a period separate from a display period of data signals thus determining a black spot defect. The position of the black spot defect is stored in a storing circuit and is transmitted to a display and detection control circuit. The display and detection control circuit corrects the data signals to the pixels around the defective pixel based on a black spot defect position, and drives a data line drive circuit based on the corrected data signals thus visually correcting the black spot defect.

### CLAIM OF PRIORITY

The present application claims priority from Japanese application serial no. 2007-162585 filed on Jun. 20, 2007, the content of which is hereby incorporated by reference into this application.

### BACKGROUND OF THE INVENTION

### Field of the Invention

The present invention relates to an image display device on which self-light-emitting elements such as EL (electro luminescence) elements, organic EL elements or other self-light-emitting display elements are mounted.

The self-light-emitting element represented by the EL (electro luminescence) element, the organic EL element or the like has a property that the light emission luminance is proportional to a quantity of an electric current which flows in the self-light-emitting element and hence, a gray scale display can be realized by controlling quantities of electric currents which flow in the self-light-emitting elements. A display device is manufactured by arranging a plurality of above-mentioned self-light-emitting elements. However, with respect to the organic EL element, due to a defect which occurs during the formation of the organic EL element, there arises a so-called black spot defect in which a pixel assumes a non-lit state. This black spot defect is one of causes which lower a yield rate of displays. A technique which visually corrects such a black spot defect by correcting display data of peripheral pixels is disclosed in SPIE (The International Society for Optical Engineering) News 10.1117/2.1200604.0195.

### SUMMARY OF THE INVENTION

However, in the technique disclosed in SPIE (The International Society for Optical Engineering) News 10.1117/2.1200604.0195, it is necessary to preliminarily know a position of the black spot defect. Accordingly, in an example in which the technique is applied to a liquid crystal display, lit states of all pixels are checked at the time of inspection to specify a position of the black spot defect, and a correction algorithm of peripheral pixels is incorporated in a program at the time of shipping. Accordingly, the shipping inspection becomes cumbersome and, at the same time, a defect which occurs when a user uses an image display device is not taken into consideration.

The present invention has been made to overcome these drawbacks, and it is an object of the present invention to provide a self-luminous display device which automatically detects a black spot defect, and can correct the black spot defect not only at the time of shipping but also during the use of the display device by a user.

According to the present invention, an image display device includes a defect position determination circuit which determines a position of a defective pixel of a self-luminous display panel, a detection-use current source arranged in the defect position determination circuit is connected with the pixel during a period separate from a display period of a data signal thus determining the defective pixel, the position of the defective pixel is stored in a storing circuit, the position of the defective pixel is transmitted to a display and detection control circuit, the display and detection control circuit corrects the data signal supplied to pixels around the defective pixel based on the position of the defective pixel, and the pixels around the defective pixel are driven based on the corrected data signal thus visually correcting the defective pixel.

Further, according to the present invention, the image display device includes a data line drive circuit and a defect position determination circuit which supply a data signal to pixels of a self-luminous display panel and determine a position of a defective pixel, a detection-use current source arranged in the data line drive circuit and the defect position determination circuit is connected with the pixel during a period separate from a display period of the data signal thus determining the defective pixel, the position of the defective pixel is stored in a storing circuit, the position of the defective pixel is transmitted to a display and detection changeover control circuit, the display and detection changeover control circuit corrects the data signal supplied to pixels around the defective pixel based on the position of the defective pixel, and the pixels around the defective pixel are driven based on the corrected data signal thus visually correcting the defective pixel.

As described above, according to the present invention, it is possible to provide a self-luminous image display device which can automatically correct a white or black defect. The present invention can be used as a display device of a data processing terminal such as a display body in a single unit, a mobile phone, a digital camera, or a PDA.

### BRIEF DESCRIPTION OF DRAWINGS

FIG. 1 is a schematic view of an image display device according to an embodiment 1;

FIG. 2 is a view showing the internal constitution of a display and detection control circuit shown in FIG. 1;

FIG. 3 is a view showing the internal constitution of a self-luminous display panel shown in FIG. 1;

FIG. 4 is a view showing the internal constitution of a black spot defect position determination circuit shown in FIG. 1;

FIG. 5 is a timing chart of display operation shown in FIG. 1;

FIG. 6 is a timing chart of detection operation shown in FIG. 1;

FIG. 7 is a timing chart of a display operation performed at a low speed compared to the timing chart shown in FIG. 5;

FIG. 8 is a timing chart of a detection operation performed at a low speed compared to the timing chart shown in FIG. 6;

FIG. 9 is a detection characteristic view of an organic EL shown in FIG. 3;

FIG. 10 is a view showing the element structure of the organic EL shown in FIG. 3;

FIG. 11 is a view showing an element state when the black spot defect is generated in the organic EL shown in FIG. 10;

FIG. 12 is a view for explaining an operation of a pixel-around-defective-pixel data correction circuit shown in FIG. 2;

FIG. 13 is a schematic view of an image display device according to an embodiment 2;

FIG. 14 is a view showing the internal constitution of a data-line-drive circuit and black spot defect position determination circuit shown in FIG. 13; and

FIG. 15 is a view showing the internal constitution of a data line and detection line common self-luminous display panel shown in FIG. 13.

### DESCRIPTION OF THE PREFERRED EMBODIMENTS

Embodiments of the present invention are explained in conjunction with attached drawings hereinafter.

### Embodiment 1

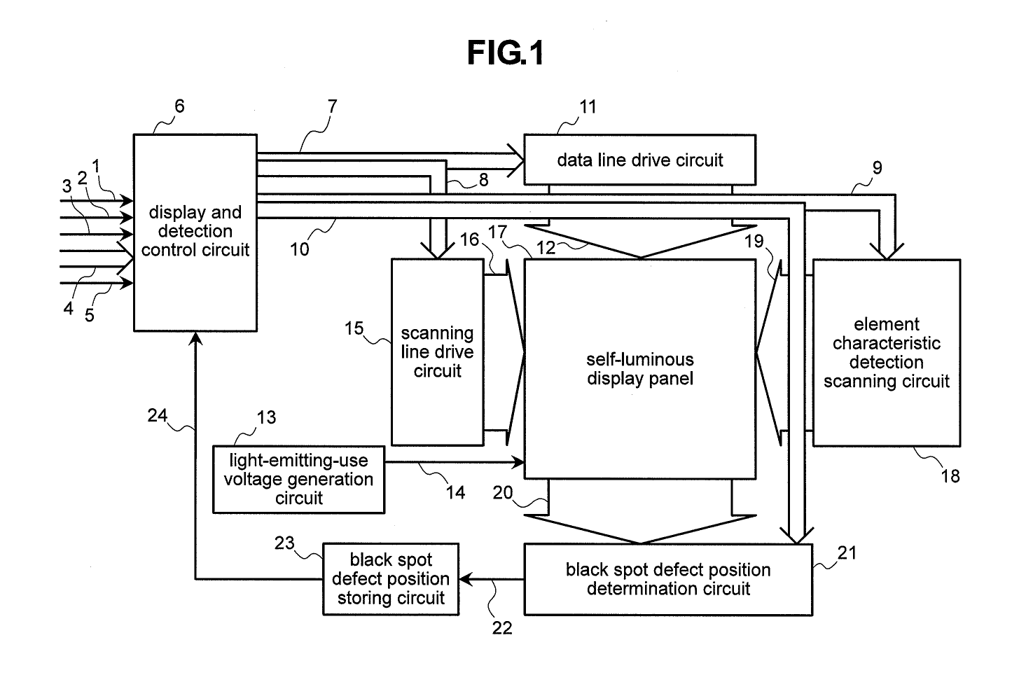

FIG. 1 is a schematic view of an image display device of this embodiment. In FIG. 1, numeral 1 indicates a horizontal synchronizing signal, numeral 2 indicates a vertical synchronizing signal, numeral 3 indicates a data enable signal, numeral 4 indicates display data, and numeral 5 indicates a synchronizing clock. The vertical synchronizing signal 1 is a signal of one screen display period (1 frame period), the horizontal synchronizing signal 2 is a signal of 1 horizontal period, the data enable signal 3 is a signal indicative of a period within which the display data 4 is effective (display effective period). All signals are inputted in synchronism with the synchronizing clock 5.

In this embodiment, the display data 4 for one screen is sequentially transferred in a raster scanning method from a pixel arranged at a left upper end of the screen. The following explanation is made assuming that the information for one pixel is formed of digital data of 6 bits. Numeral 6 indicates a display and detection control circuit, numeral 7 indicates a data line control signal, numeral 8 indicates a scanning line control signal, numeral 9 indicates a detection scanning line control signal, and numeral 10 indicates a detection line control signal. The display and detection control circuit 6 generates the data line control signal 7 and the scanning line control signal 8 for display control, and a detection scanning line control signal 9 and a detection line control signal 10 for detecting the characteristic of a display element described later based on the vertical synchronizing signal 1, the horizontal synchronizing signal 2, the data enable signal 3, the display data 4 and the synchronizing clock 5.

Numeral 11 indicates a data line drive circuit, and numeral 12 indicates a data line drive signal. The data line drive circuit 11 generates a signal voltage and a triangular wave signal written in pixels each of which is constituted of a self-light-emitting element based on the data line control signal 7, and outputs the signal voltage and the triangular wave signal as the data line drive signal 12. Numeral 13 indicates a light-emitting-use voltage generation circuit (for example, a constant voltage source), and numeral 14 indicates a light-emitting-use voltage. The light-emitting-use voltage generation circuit 13 generates a power source voltage for supplying electric current which enable the self-light-emitting element to emit light and output the power source voltage as the light-emitting-use voltage 14.

Numeral 15 indicates a scanning line drive circuit, numeral 16 indicates a scanning line selection signal, and numeral 17 indicates a self-luminous display panel. The self-luminous display panel 17 is a panel which uses light emitting diodes, organic EL or the like as display elements. The self-luminous display panel 17 includes a plurality of self-light-emitting elements (pixels) arranged in a matrix array. In performing a display operation of the self-luminous display panel 17, a signal voltage corresponding to the data line drive signal 12 outputted from the data line drive circuit 11 is written in the pixels selected based on the scanning line drive signal 16 outputted from the scanning line drive circuit 15 during a writing period, and light is emitted based on the triangular wave signal. A voltage for driving the self-light-emitting elements is supplied as the light-emitting-use voltage 14. Here, the data line drive circuit 11 and the scanning line drive circuit 15 may be respectively formed using LSIs. The data line drive circuit 11 and the scanning line drive circuit 15 may be respectively formed using only one LSI. Further, the data line drive circuit 11 and the scanning line drive circuit 15 may be formed on the same glass substrate on which pixel portions are formed.

In this embodiment, the explanation is made with respect to the self-luminous display panel 17 which has the resolution of 240×320 dots, wherein one dot is constituted of three pixels of R (Red), G (Green) and B (Blue) from the left side. That is, 720 pieces of pixels are arranged in the horizontal direction of the panel. The self-luminous display panel 17 can adjust the luminance of the light emitted by the self-light-emitting element based on a quantity of an electric current which flows in the self-light-emitting element and a lit period of the self-light-emitting element. The larger a quantity of the electric current which flows in the self-light-emitting element, the higher the luminance of the self-light-emitting element becomes. The longer the lit period of the self-light-emitting element, the higher the luminance of the self-light-emitting element becomes.

Numeral 18 indicates an element characteristic detection scanning circuit, and numeral 19 indicates a detection scanning line selection signal. The element characteristic detection scanning circuit 18 generates a detection scanning line selection signal 19 for selecting a scanning line along which the presence or the non-presence of a defect in the self-light-emitting element of the self-luminous display panel 17 is detected.

Numeral 20 indicates a detection line output signal, numeral 21 indicates a black spot defect position determination circuit, and numeral 22 indicates a black spot defect detection result. The detection line output signal 20 is generated as a result of detection of the presence or the non-presence of a defect in the self-light-emitting element on 1 horizontal line selected based on the detection scanning line selection signal 19 of the self-luminous display panel 17, and is outputted as the black spot defect detection result 22 when the presence of the defect is determined by the black spot defect position determination circuit 21. Numeral 23 indicates a black spot defect position storing circuit, and numeral 24 indicates black spot defect position information. The black spot defect position storing circuit 23 stores the black spot defect detection result 22 and outputs black spot defect position information 24.

In this embodiment, the explanation is made by assuming as follows. That is, the black spot defect detection result 22 implies the outputting of address information indicative of the position of the pixel on the screen and the presence or non-presence information of a black spot defect at the position. The black spot defect position information storing circuit 23 stores the presence or the non-presence information of the black spot at an address corresponding to the black spot defect detection result 22, and the black spot defect position information 24 implies the outputting of the presence or non-presence of the defect in conformity with display timing.

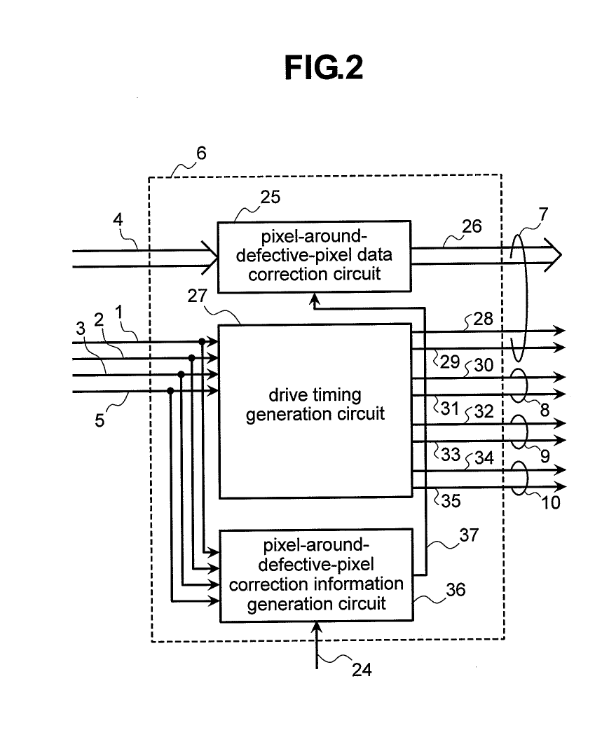

FIG. 2 is a view showing the internal constitution of the display and detection control circuit 6 shown in FIG. 1. In FIG. 2, numeral 25 indicates a pixel-around-defective-pixel data correction circuit, and numeral 26 indicates display correction data. The pixel-around-defective-pixel data correction circuit 25, based on pixel-around-defective-pixel correction information 37, corrects the data of the pixel around the defective pixel out of the display data 4, does not correct other pixels, and outputs the corrected data as the display correction data 26.

Numeral 27 indicates a drive timing generation circuit, numeral 28 indicates a horizontal start signal, numeral 29 indicates a horizontal shift clock, numeral 30 indicates a vertical start signal, and numeral 31 indicates a vertical shift clock. The drive timing generation circuit 27, in the same manner as a conventional driving timing generation circuit, generates the horizontal start signal 28 indicative of a head of the display horizontal position, the horizontal shift clock 29 generating timing for latching the display data 4 for every one pixel, the vertical start signal 30 indicative of a head of the display vertical position, and the vertical shift clock 31 for sequentially shifting the selection of scanning line.

Numeral 32 indicates a vertical detection start signal, numeral 33 indicates a vertical detection shift clock, numeral 34 indicates a horizontal detection start signal, and numeral 35 indicates a horizontal detection shift clock. The drive timing generation circuit 27 generates the vertical detection start signal 32 indicative of a head of the detection operation in the vertical direction, the vertical detection shift clock 33 which sequentially shifts the detection scanning line, the horizontal detection start signal 34 indicative of a head of the detection horizontal position, and the horizontal detection shift clock 35 which sequentially shifts the detection horizontal position.

Numeral 36 indicates a pixel-around-defective-pixel correction information generation circuit, and numeral 37 indicates pixel-around-defective-pixel correction information. The pixel-around-defective-pixel correction information generation circuit 36, based on the black spot defect position information 24, determines positions of pixels around the defective pixel and outputs correction quantities for the peripheral pixels to the pixel-around-defective-pixel data correction circuit 25 as the pixel-around-defective-pixel correction information 37.

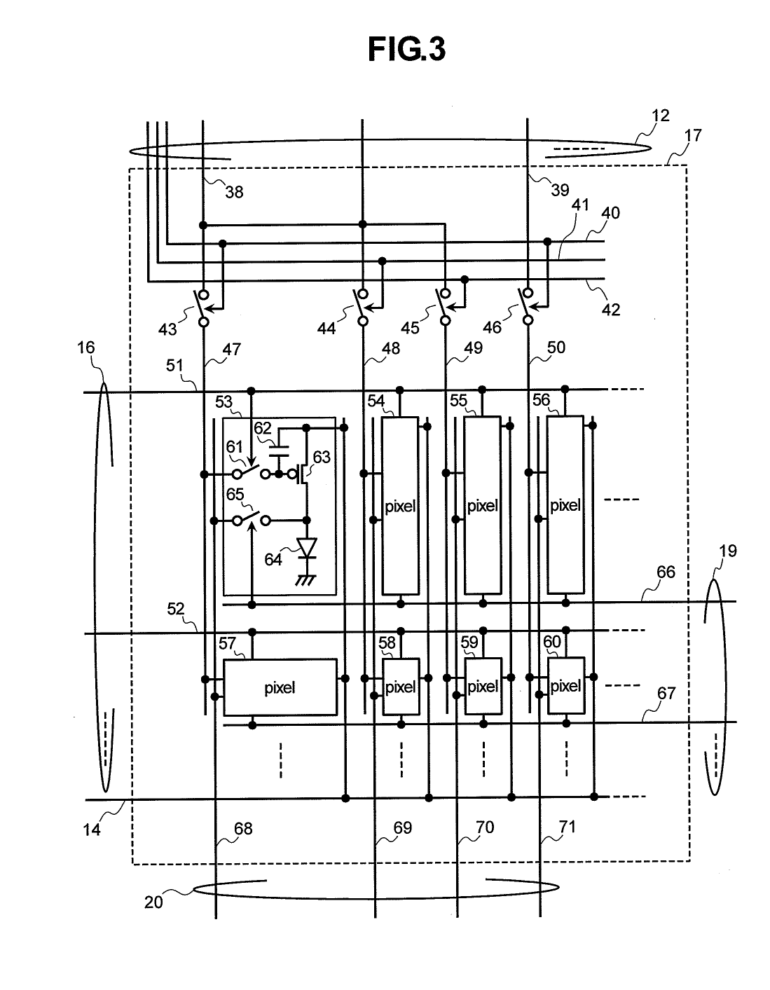

FIG. 3 is a view showing the internal constitution of the self-luminous display panel 17 shown in FIG. 1. FIG. 3 shows a case in which an organic EL element is used as an example of the self-light-emitting element. In FIG. 3, numeral 38 indicates a first data line output, numeral 39 indicates a second data line output, numeral 40 indicates an R selection signal, numeral 41 indicates a G selection signal, numeral 42 indicates a B selection signal, numeral 43 indicates a first R selection switch, numeral 44 indicates a first G selection switch, numeral 45 indicates a first B selection switch, and numeral 46 indicates a second R selection switch.

The first data line output 38 is connected to the first R selection switch 43 which is changed over based on the R selection signal 40, the first G selection switch 44 which is changed over based on the G selection signal 41, and the first B selection switch 45 which is changed over based on the B selection signal 42. Thereafter, all remaining data line outputs ranging from the second, the third . . . , to the 240th data line output are connected to the R, G, B selection switches.

In this embodiment, the explanation is made assuming that 1 horizontal period is divided in three and the R selection signal 40, the G selection signal 41 and the B selection signal 42 are signals which sequentially assume an “ON” state in the respective divided periods, and one data line output outputs a signal voltage to three data lines of RGB. That is, the self-luminous display panel 17 is driven by RGB time-division processing. Numeral 47 indicates a first R data line, numeral 48 indicates a first G data line, numeral 49 indicates a first B data line, numeral 50 indicates a second R data line, numeral 51 indicates a first scanning line, numeral 52 indicates a second scanning line, numeral 53 indicates a first-row first-column R pixel, numeral 54 indicates a first-row first-column G pixel, numeral 55 indicates a first-row first-column B pixel, numeral 56 indicates a first-row second-column R pixel, numeral 57 indicates a second-row first-column R pixel, numeral 58 indicates a second-row first-column G pixel, numeral 59 indicates a second-row first-column B pixel, and numeral 60 indicates a second-row second-column R pixel. Here, three data lines of RGB may be connected to three data lines 38 so as to output signal voltages to the three data lines of RGB for 1 horizontal period in parallel.

The first R data line 47, the first G data line 48, the first B data line 49, the second R data line 50 are data lines for inputting respective signal voltages to the pixels. The first scanning line 51 and the second scanning line 52 are signal lines for respectively inputting the first scanning line selection signal and the second scanning line selection signal to the pixels. The signal voltages are written in the pixels on the scanning lines selected by the respective scanning line selection signals via the respective data lines so that the luminance of the pixels are controlled in accordance with the signal voltages. The power source for emitting light at this time assumes the light-emitting-use voltage 14.

Here, the constitution of the inside of the pixel is shown only with respect to the first-row first-column R pixel 53. However, the first-row first-column G pixel 54, the first-row first-column B pixel 55, the first-row second-column R pixel 56, the second-row first-column R pixel 57, the second-row first-column G pixel 58, the second-row first-column B pixel 59 and the second-row second-column R pixel 60 have the substantially same constitution as the first-row first-column R pixel 53.

With respect to the constitution in the inside of the pixel, numeral 61 indicates a data writing switch, numeral 62 indicates a writing capacitance, numeral 63 indicates a drive transistor, and numeral 64 indicates an organic EL. The data writing switch 61 is turned on based on a scanning signal supplied via the first scanning line 51 and stores the signal voltage from the first R data line 47 in the writing capacitance 62. The drive transistor 63 supplies a drive current corresponding to the signal voltage stored in the writing capacitance 62 to the organic EL 64. Accordingly, the luminance of the light emission of the organic EL 64 is determined based on the signal voltage to be written in the writing capacitance 62 and the light-emitting-use voltage 14. Further, in this embodiment, with respect to the number of pixels arranged in the self-luminous display panel 17, since the resolution is set to 240×320, as the scanning lines, 320 pieces of horizontal lines consisting of a first line to a 320th line are arranged parallel to each other in the vertical direction. On the other hand, as the data lines, 240 pieces of vertical lines ranging from a first dot to a 240th dot are arranged parallel to each other in the horizontal direction for R, G, B respectively. That is, 720 pieces of data lines in total are arranged in the horizontal direction.

Further, with respect to the constitution in the inside of the pixel, numeral 65 indicates a detection switch, numeral 66 indicates a first detection scanning line, numeral 67 indicates a second detection scanning line, numeral 68 indicates a first detection line, numeral 69 indicates a second detection line, numeral 70 indicates a third detection line, and numeral 71 indicates a fourth detection line. The detection switch 65 is a switch for outputting the characteristic of the organic EL 64 to the first detection line 68 when the detection switch 65 is selected by a scanning signal supplied via the first detection scanning line 66. The second detection scanning line 67, the second detection line 69, the third detection line 70, and the fourth detection line 71 are also connected to the organic EL elements via the detection switches of the respective pixels in the same manner. Hereinafter, the explanation is also made assuming that 720 pieces of detection lines are arranged.

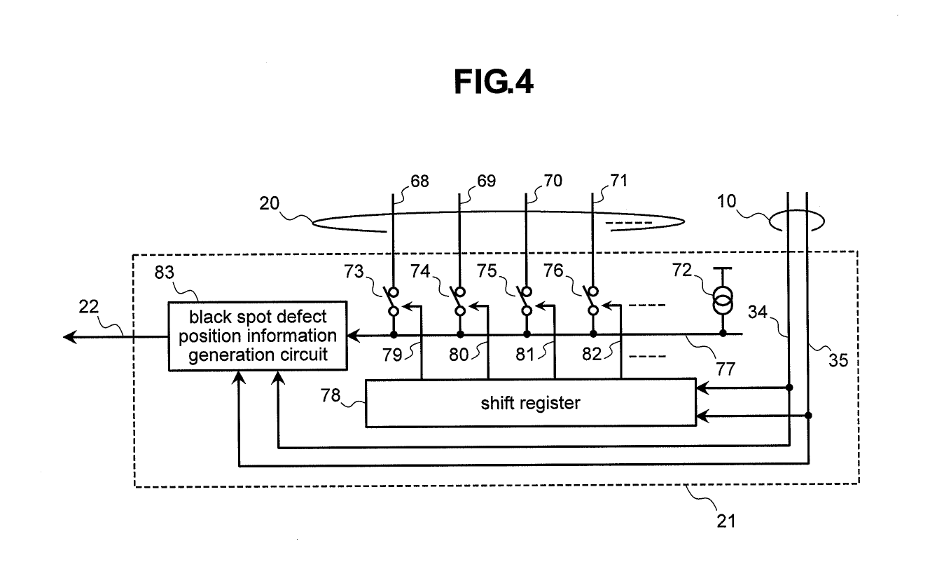

FIG. 4 is the view showing the internal constitution of the black spot defect position determination circuit 21 shown in FIG. 1. In FIG. 4, numeral 72 indicates a detection-use current source, numeral 73 indicates a first detection line switch, numeral 74 indicates a second detection line switch, numeral 75 indicates a third detection line switch, numeral 76 indicates a fourth detection line switch, and numeral 77 indicates a detection output line. The first detection line switch 73, the second detection line switch 74, the third detection line switch 75, and the fourth detection line switch 76 are sequentially shifted and are selected in the horizontal direction by the shift register 78 and hence, the characteristic of the organic EL element when the detection-use current source 72 is sequentially connected to the first detection line 68, the second detection line 69, the third detection line 70, the fourth detection line 71, . . . , a 720th detection line is outputted to the detection output line 77.

Numeral 78 indicates a shift register, numeral 79 indicates a first detection line selection signal, numeral 80 indicates a second detection line selection signal, numeral 81 indicates a third detection line selection signal, and numeral 82 indicates a fourth detection line selection signal. Based on the horizontal detection start signal 34 and the horizontal detection shift clock 35, the shift register 78 outputs the first detection line selection signal 79, the second detection line selection signal 80, the third detection line selection signal 81, and the fourth detection line selection signal 82 for sequentially changing over the detection line switches 73 to 76.

Numeral 83 indicates a black spot defect position information generation circuit which determines the position of the pixel based on the horizontal detection start signal 34 and the horizontal detection shift clock and, at the same time, determines the presence or the non-presence of the black spot defect based on the characteristic of the organic EL element which is sequentially outputted from the detection output line 77, and outputs the address of the pixel and the presence or the non-presence of the defect as the black spot defect detection result 22.

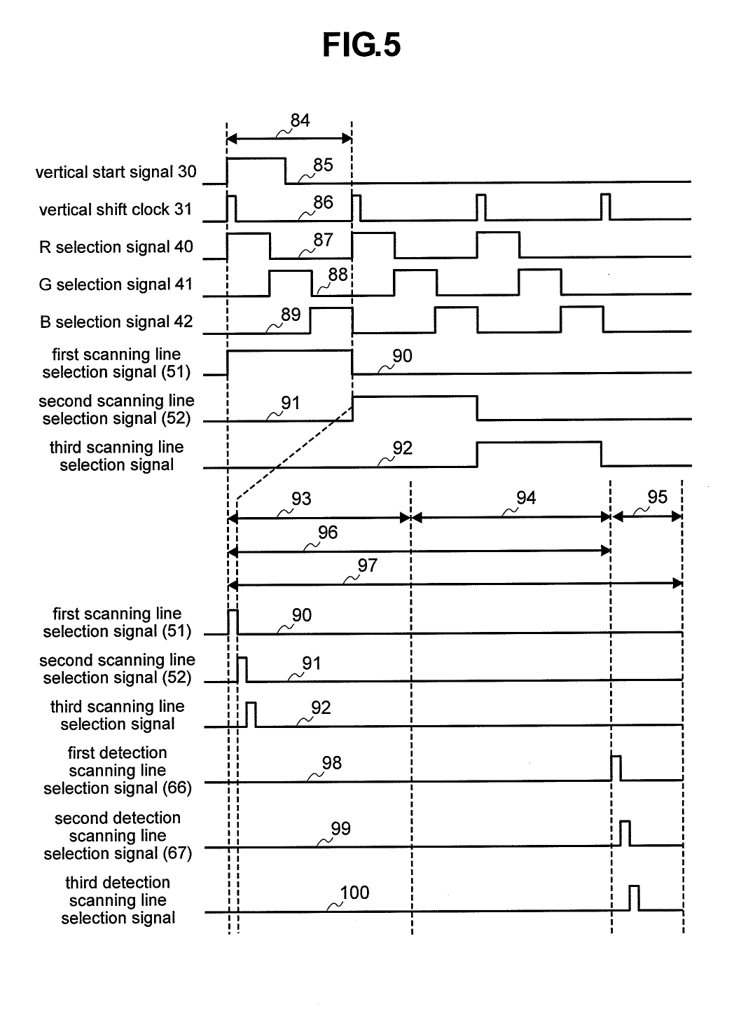

FIG. 5 is a timing chart of a display operation and a detection operation performed by the scanning line drive circuit 15, the element characteristic detection scanning circuit 18 and the black spot defect position determination circuit 21 shown in FIG. 1, and FIG. 5 particularly shows a timing chart of the display operation. In FIG. 5, numeral 84 indicates 1 horizontal period, numeral 85 indicates a vertical start signal waveform, numeral 86 indicates a vertical shift clock waveform, numeral 87 indicates an R selection signal waveform, numeral 88 indicates a G selection signal waveform, numeral 89 indicates a B selection signal waveform, numeral 90 indicates a first scanning line selection signal waveform, numeral 91 indicates a second scanning line selection signal waveform, and numeral 92 indicates a third scanning line selection signal waveform. In the same manner as a conventional technique, the vertical start signal waveform 85 is sequentially shifted in accordance with the vertical shift clock waveform 86 so that the first scanning line selection signal waveform 90, the second scanning line selection signal waveform 91 and the third scanning line selection signal waveform 92 are generated. Within 1 horizontal period 84, respective scanning line selection signals assume a “High” state, and the R selection signal waveform 87, the G selection signal waveform 88, the B selection signal waveform 87 sequentially assume a “High” state by dividing 1 horizontal period 84 in three.

Numeral 93 indicates a display signal writing period, numeral 94 indicates a display period, numeral 95 indicates a detection period, numeral 96 indicates a display drive period, numeral 97 indicates 1 display period, numeral 98 indicates a first detection scanning line selection signal waveform, numeral 99 indicates a second detection scanning line selection signal waveform, and numeral 100 indicates a third detection scanning line selection signal waveform. The display signal writing period 93 is a period within which the respective scanning line selection signals select whole scanning lines for one screen and writing the data signals. The display period 94 is a period from a point of time that the writing of the data signals is finished to a point of time that the detection operation is started. That is, the display period 94 is a period within which the whole pixels emit light. A combined period of the display signal writing period 93 and the display period 94 is a display drive period 96. Within the detection period 95, the detection scanning line selection signals sequentially assume a “High” state, and a combined period of the display drive period 96 and the detection period 95 is 1 display period 97. This 1 display period 97 is a period which is generally referred to as 1 frame period. Further, the display period 94 or the detection period 95 may be included in a retracing (blanking) period. Further, the order of the display period 94 and the detection period 95 may be reversed. Further, in place of separately providing the display signal writing period 93, the display period 94 and the detection period 95 for every 1 frame period (for every one screen), the display signal writing period 93, the display period 94 and the detection period 95 may be separately provided for every 1 horizontal period (for every 1 horizontal line).

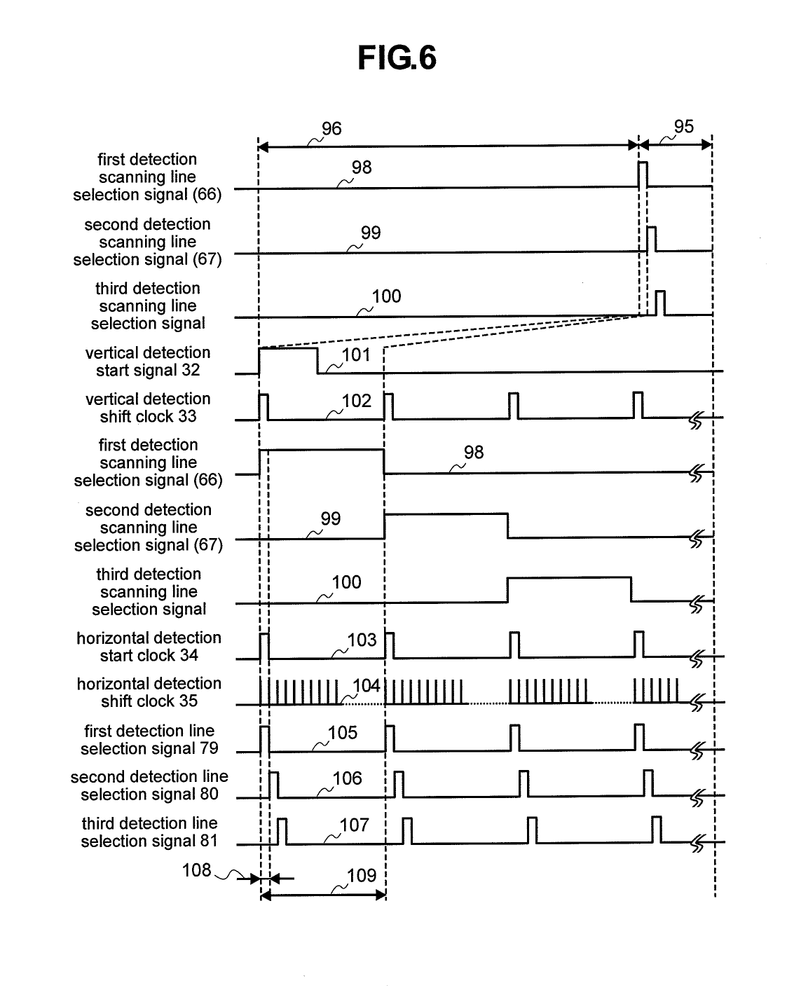

FIG. 6 is a timing chart of a display operation and a detection operation performed by the scanning line drive circuit 15, the element characteristic detection scanning circuit 18 and the black spot defect position determination circuit 21 shown in FIG. 1, and FIG. 6 particularly shows a timing chart of the detection operation. In FIG. 6, numeral 101 indicates a vertical detection start signal waveform, and numeral 102 indicates a vertical detection shift clock waveform. The vertical detection start signal waveform 101 is, during the detection period 95, sequentially shifted in accordance with the vertical detection shift clock waveform 102 so that the first detection scanning line selection signal waveform 98, the second detection scanning line selection signal waveform 99 and the third detection scanning line selection signal waveform 100 are generated.

Numeral 103 indicates a horizontal detection start signal waveform, numeral 104 indicates a horizontal detection shift clock, numeral 105 indicates a first detection line selection signal waveform, numeral 106 indicates a second detection line selection signal waveform, numeral 107 indicates a third detection line selection signal waveform, numeral 108 indicates a one pixel characteristic detection period, and numeral 109 indicates a 1 horizontal line characteristic detection period. The horizontal detection start signal waveform 103 is, during the 1 horizontal line characteristic detection period 109, sequentially shifted in accordance with the horizontal detection shift clock waveform 104 so that the first detection line selection signal waveform 105, the second detection line selection signal waveform 106 and the third detection line selection signal waveform 107 which respectively assume a “High” state during the one pixel characteristic detection period 108 are generated.

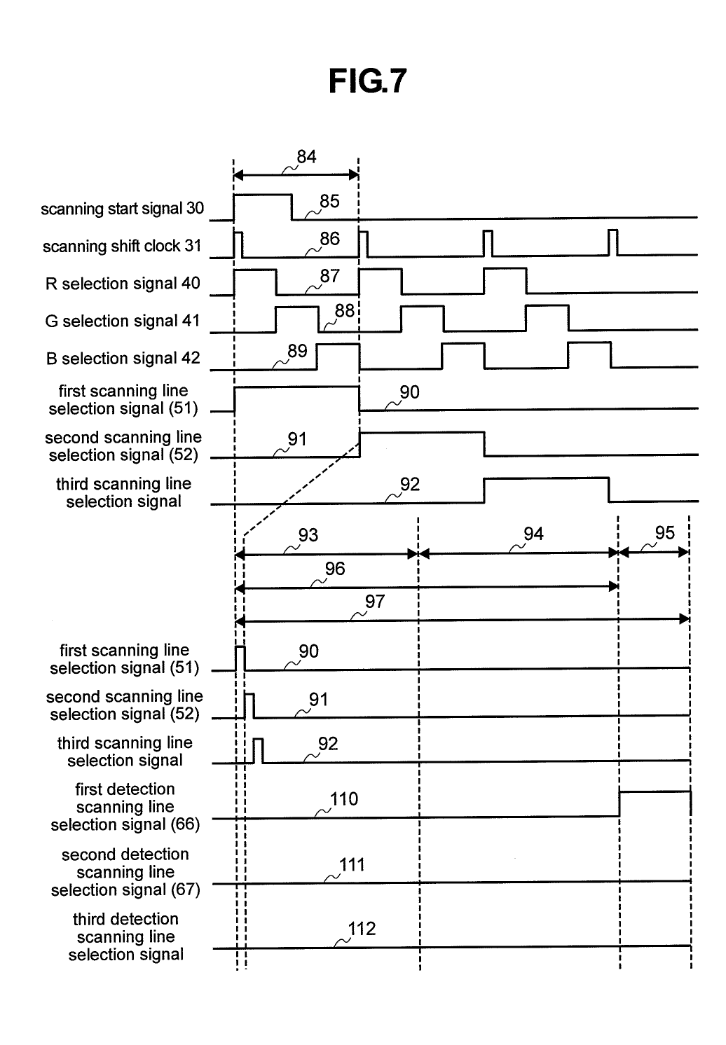

FIG. 7 is a timing chart of a display operation and a detection operation performed by the scanning line drive circuit 15, the element characteristic detection scanning circuit 18 and the black spot defect position determination circuit 21 shown in FIG. 1. Compared to the timing chart shown in FIG. 5, the operations are performed at a low speed. Further, FIG. 7 particularly shows the timing chart of the display operation. In FIG. 7, numeral 110 indicates a first detection scanning line selection signal waveform at low-speed-operation detection, numeral 111 indicates a second detection scanning line selection signal waveform at low-speed-operation detection, and numeral 112 indicates a third detection scanning line selection signal waveform at low-speed-operation detection. The respective detection scanning line selection signal waveforms at low-speed-operation detection imply that any one of the respective detection scanning line selection signal waveforms at low-speed-operation detection assumes a “High” state during the detection period 95, that is, the detection for 1 scanning line is performed within 1 display period 97.

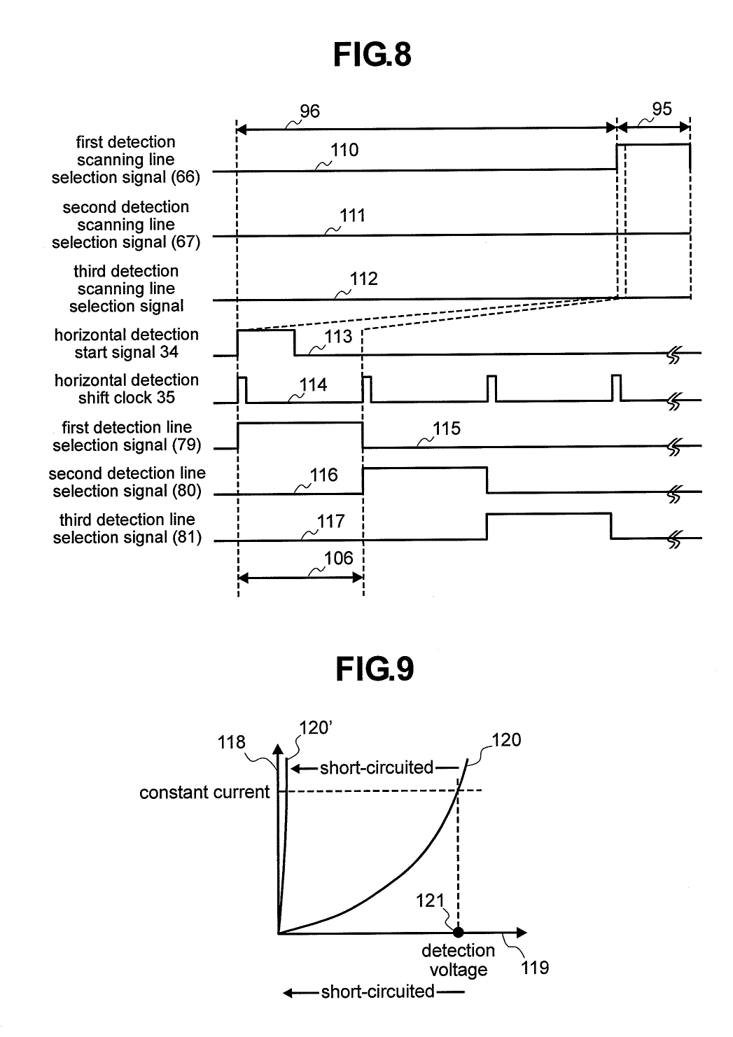

FIG. 8 is a timing chart of a display operation and a detection operation performed by the scanning line drive circuit 15, the element characteristic detection scanning circuit 18 and the black spot defect position determination circuit 21 shown in FIG. 1. Compared to the timing chart shown in FIG. 6, the operations are performed at a low speed. Further, FIG. 8 particularly shows the timing chart of the detection operation. In FIG. 8, numeral 113 indicates a horizontal detection start signal waveform at low-speed-operation detection, numeral 114 indicates a horizontal detection shift clock waveform at low-speed-operation detection, numeral 115 indicates a first detection line selection signal waveform at low-speed-operation detection, numeral 116 indicates a second detection line selection signal waveform at low-speed-operation detection, and numeral 117 indicates a third detection line selection signal waveform at low-speed-operation detection. The horizontal detection start signal waveform 113 at low-speed-operation detection is, during the detection period 95, sequentially shifted in accordance with the horizontal detection shift clock waveform 114 at low-speed-operation detection so that the first detection line selection signal waveform 115 at low-speed-operation detection, the second detection line selection signal waveform 116 at low-speed-operation detection and the third detection line selection signal waveform 117 at low-speed-operation detection which respectively assume a “High” state during the one pixel characteristic detection period 108 are generated.

FIG. 9 is a detection characteristic view of the organic EL 64 shown in FIG. 3. In FIG. 9, numeral 118 indicates an axis of ordinates on which an electric current is taken, numeral 119 indicates an axis of abscissas on which a voltage is taken, numeral 120 indicates an organic EL current/voltage characteristic, and numeral 121 indicates a constant-current-applied-time voltage. The organic EL current/voltage characteristic 120 shows the relationship between a voltage and a current respectively applied to the organic EL 64. Here, in detecting the characteristic of the organic EL 64, the detection-use current source 72 shown in FIG. 4 is connected to the organic EL 64 and hence, the constant-current-applied-time voltage 121 acquired when a constant-current on a curve of the organic EL current/voltage characteristic 120 is applied to the organic EL 64 becomes a characteristic voltage to be detected. However, when the organic EL is short-circuited, an organic EL current/voltage characteristic curve is shifted to 120′ from 120, and the detected voltage becomes equal to or less than a threshold voltage (for example, approximately zero). In this manner, the state of the organic EL can be detected. Here, the current may be detected using a constant voltage source in place of the constant current source.

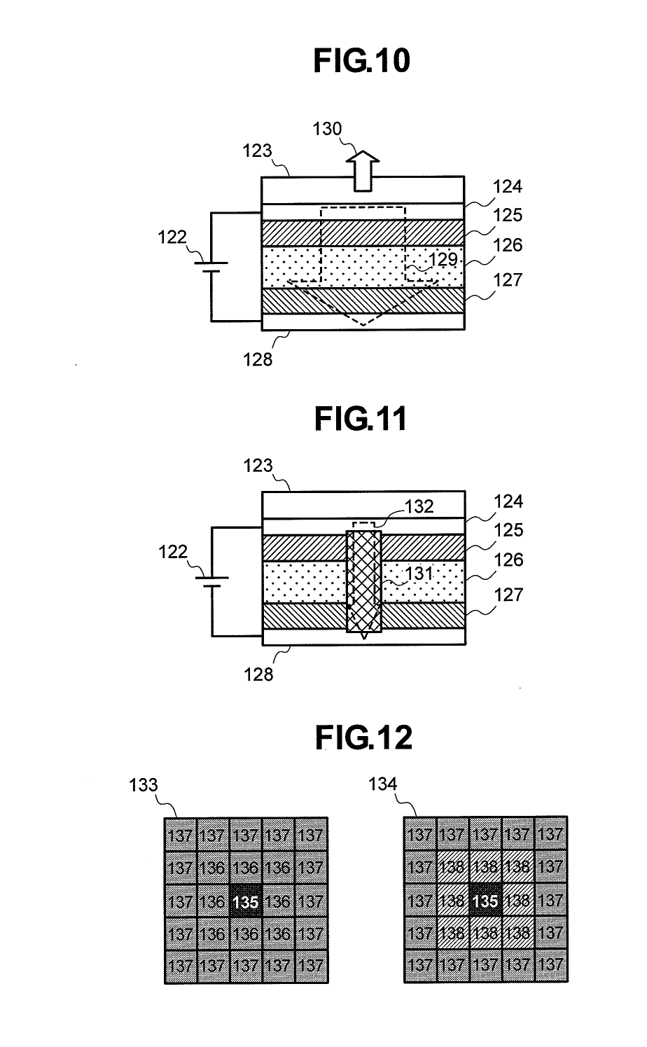

FIG. 10 is a view showing the element structure of the organic EL 64 shown in FIG. 3. In FIG. 10, numeral 122 indicates a light emitting power source, numeral 123 indicates a glass substrate, numeral 124 indicates a transparent electrode, numeral 125 indicates a hole transport layer, numeral 126 indicates a light emitting layer, numeral 127 indicates an electron transport layer, numeral 128 indicates a metal electrode, numeral 129 indicates a light emitting current, and numeral 130 indicates an optical output. In the same manner as a conventional technique, the light emitting layer 126 emits light when the current 129 flows in light emitting layer 126 thus generating an optical output 130.

FIG. 11 is a view showing an element state when the black spot defect is generated in the organic EL shown in FIG. 10. In FIG. 11, numeral 131 indicates a foreign material mixed at the time of forming a film, and numeral 132 indicates a foreign material inflow current. The foreign material 131 mixed at the time of forming a film is adhered to the element at the time of forming the film such as the light emitting layer 126. When the foreign material 131 is of a material which possesses conductivity, the current from the light emitting power source 122 flows only in the foreign material 131 at the time of forming the film as the foreign material inflow current 132 and does not flow in the light emitting layer 126. As a result, the light emitting layer does not emit light and hence, a white or black defect occurs. Here, since the transparent electrode 124 and the metal electrode 128 are short-circuited to each other due to the foreign material 131 at the time of forming the film, the detection voltage shown in FIG. 9 becomes almost “0”. This “almost 0” state can be determined as the white or black defect state. Here, when the element is free from the foreign material 131, the detection voltage assumes a value equal to or more than a threshold voltage (for example, infinite).

FIG. 12 is an explanatory view of a data correction operation on pixels around the defective pixel performed by the pixel-around-defective-pixel data correction circuit 25 shown in FIG. 2. In FIG. 12, numeral 133 indicates black-spot-defect pre-correction data, numeral 134 indicates black-spot-defect post-correction data, numeral 135 indicates a black-spot defective pixel, numeral 136 indicates the pixels around the black-spot defective pixel 135 before correction, numeral 137 indicates the pixels without correction, and numeral 138 indicates the pixels around the black-spot defective pixel 135 after correction. The luminance of the pixels 136 around the black-spot defective pixel 135 before correction is increased so as to compensate for the reduction of luminance of the black-spot defective pixel 135 thus forming the pixels 138 around black-spot defective pixel 135 after correction whereby the black-spot defective pixel 135 is visually corrected. In this embodiment, the following explanation is made assuming the pixels 136 around the black-spot defective pixel 135 before correction and the pixels 138 around the black-spot defective pixels 135 after correction as pixels adjacent to the black-spot defective pixel 135 and other pixels as the pixels 137 without correction.

Hereinafter, the black spot defect detection and correction performed in this embodiment are explained in conjunction with FIG. 1 to FIG. 12. First of all, the flow of the display data is explained in conjunction with FIG. 1. In FIG. 1, the display and detection control circuit 6 generates the data line control signal 7 and the scanning line control signal 8 which are necessary for generating display timing of the self-luminous display panel 17 in the same manner as the conventional technique based on the horizontal synchronizing signal 1, the vertical synchronizing signal 2, the data enable signal 3 and, the synchronizing clock 5. At the same time, the display and detection control circuit 6 generates the detection scanning line control signal 9 and the detection line control signal 10 which are necessary for generating timing for detecting states of the pixels in the self-luminous display panel 17. The data line drive circuit 11, the scanning line drive circuit 15 and the light-emitting-use voltage generation circuit 13 are operated in the same manner as the corresponding parts used in the conventional technique.

The element characteristic detection scanning circuit 18 generates the detection scanning line selection signal 19 based on the detection scanning line control signal 9 for scanning the pixels to be detected in a detection period provided separately from a conventional period of display operation. The black spot defect position determination circuit 21 determines the presence or the non-presence of the black spot defect based on a state of the detection line output signal 20 which reflects the characteristic of a pixel arranged on the scanning line selected by the detection scanning line selection signal 19 and, at the same time, determines the position of the pixel based on the detection line control signal 10 thus generating the black spot defect detection result 22 constituted of the address information and black-spot-defect presence-or-non-presence information to be stored in the black spot defect position information storing circuit 23. The black spot defect position information 24 is the presence-or-non-presence information of the black spot defect read from the black spot defect position information storing circuit 23 at display timing.

The detail of the generation of timing of the display and detection control circuit 6 shown in FIG. 1 is explained in conjunction with FIG. 2 and FIG. 5 to FIG. 8. In FIG. 2, the pixel-around-defective-pixel data correction circuit 25 corrects only the data on the pixels around the defective pixel out of the display data 4 (pixels included in a preset region with respect to the position of the defective pixel) and outputs the pixel data as the display correction data 26 without correcting data on pixels other than the pixel-around-defective-pixels. Here, in place of correcting the data, a correction voltage maybe applied to the data signal. Further, a light-emitting-use voltage and a triangular wave signal may be corrected. The drive timing generation circuit 27 generates, in the same manner as a conventional drive timing generation circuit, the horizontal start signal 28, the horizontal shift clock 29, the vertical start signal 30, and the vertical shift clock 31 as shown in FIG. 5 and FIG. 7. Further, the drive timing generation circuit 27, as shown in FIG. 5, during 1 display period 97, generates the vertical detection start signal 32 and the vertical detection shift clock 33 as timing signals for scanning the detection scanning line during a detection period 95 provided separately from the display drive period 96 and, as shown in FIG. 6, generates the horizontal detection start signal 34 and the horizontal detection shift clock 35 as timing signals for sequentially outputting the states of the pixels on the selected detection scanning line in the horizontal direction. Here, in FIG. 5 and FIG. 6, the detection scanning lines for one screen are scanned within a detection period 95. That is, the detection of pixels for one screen is finished within 1 display period 97. However, when the detection requires some time, the pixels in a half or a quarter of the screen may be detected within 1 display period 97. In such a case, the detection of pixels for one screen may be finished within a plurality of display periods. As shown in FIG. 7 and FIG. 8, the pixels on 1 horizontal line may be detected within the detection period 95. In this case, the detection of pixels for one screen may be finished within 320 display periods. Further, the detection period 95 may be provided to 1 horizontal period. Further, the detection period 95 may be provided at the time of starting the image display device, for example, during a period from a point of time that the power source is supplied to a point of time that the display based on the display data starts, or these periods may be combined. In the present invention, except for that the detection period 95 is provided separately from the display drive period 96, the number of scanning lines to be detected or the like is not limited.

The detail of the black spot defect detection operation performed by the self-luminous display panel 17 and the black spot defect position determination circuit 21 shown in FIG. 1 is explained in conjunction with FIG. 3, FIG. 4 and FIG. 9 to FIG. 11. In FIG. 3, based on the scanning line selection signals sequentially outputted via the first detection scanning line 66 and the second detection scanning line 67, the organic ELs of the respective pixels are connected to the first detection line 68, the second detection line 69, the third detection line 70, and the fourth detection line 71 to the 320th detection line (not shown in the drawing) via the detection switches of the respective pixels, and the respective characteristics are outputted as the detection line output signals 20.

In FIG. 4, the detection line output signal 20 is sequentially shifted and changed over in the horizontal direction in accordance with the first detection line selection signal 79, the second detection line selection signal 80, the third detection line selection signal 81 and the fourth detection line selection signal 82 generated by the shift register 78 based on the detection horizontal start signal 34 and the detection horizontal shift clock 35 via the first detection line switch 73, the second detection line switch 74, the third detection line switch 75 and the fourth detection line switch 76, and is outputted to the detection output line 77. Here, the organic EL 64 shown in FIG. 3 is connected to the detection-use current source 72 shown in FIG. 4 and hence, the organic EL 64 having the characteristic shown in FIG. 9 outputs the constant-current-applied-time voltage 121 to the detection line output signal 20 as the detection voltage.

As shown in FIG. 10, when the organic EL 64 is normal, the electric current 129 flows in the light emitting layer 126 and hence, the optical output 130 is acquired and, at the same time, as shown in FIG. 9, the constant-current-applied-time voltage 121 is detected as a voltage indicative of a state of the element. On the other hand, when a foreign material is mixed in the element at the time of forming the element as a film as shown in FIG. 11, the foreign-material inflow current 132 flows in the film-forming-time mixed foreign material 131 and hence, an electric current does not flow in the light emitting layer 126. As the result, the light emitting layer 126 does not emit light thus generating a black spot defect and, at the same time, a voltage at the time of applying a constant current is detected as “approximately 0”.

Due to the above-mentioned operations, in FIG. 1, the black-spot detect-position determination circuit 21 outputs the presence or non-presence of a black spot in the pixel within the self-luminous display panel 17 and the positional information of the black spot as the black-spot defect detection result 22. Finally, using FIG. 2 and FIG. 12, the detail of the black spot correction operation using the defect peripheral pixel data correction circuit 25 shown in FIG. 2 is explained. In FIG. 12, for correcting the pre-correction black-spot peripheral pixel 136, the defect peripheral pixel correction information generation circuit 36 shown in FIG. 2 specifies the black spot peripheral pixel and the correction quantity based on the black spot defect positional information 24, and outputs the specified values as the defect peripheral pixel correction information 37. The defect peripheral pixel data correction circuit 25, in accordance with the defect peripheral pixel correction information 37, generates the display correction data 26. For example, as shown in FIG. 12, the luminance of the pre-correction black spot peripheral pixel 136 is increased so as to compensate for the reduction of luminance of the black-spot defective pixel 135 thus forming the post-correction black spot peripheral pixel 138 whereby the black-spot defective pixel 135 is visually corrected. Here, although the pre-correction black-spot peripheral pixel (i.e., the pixels around the black-spot defective pixel 135 before corrections) 136 and the post-correction black spot peripheral pixel (i.e., the pixels around the black-spot defective pixel 135 after correction) 138 are only limited to the pixels adjacent to the black-spot defective pixel 135, these peripheral pixels 136, 138 are not limited to these neighboring pixels and may include pixels around these peripheral pixels. Further, the degree of correction is not also limited. Due to the above-mentioned operations, the display and detection control circuit 6 performs the black spot correction in accordance with the black spot defect positional information 24 from the black-spot defect position information storing circuit 23 shown in FIG. 1.

### Embodiment 2

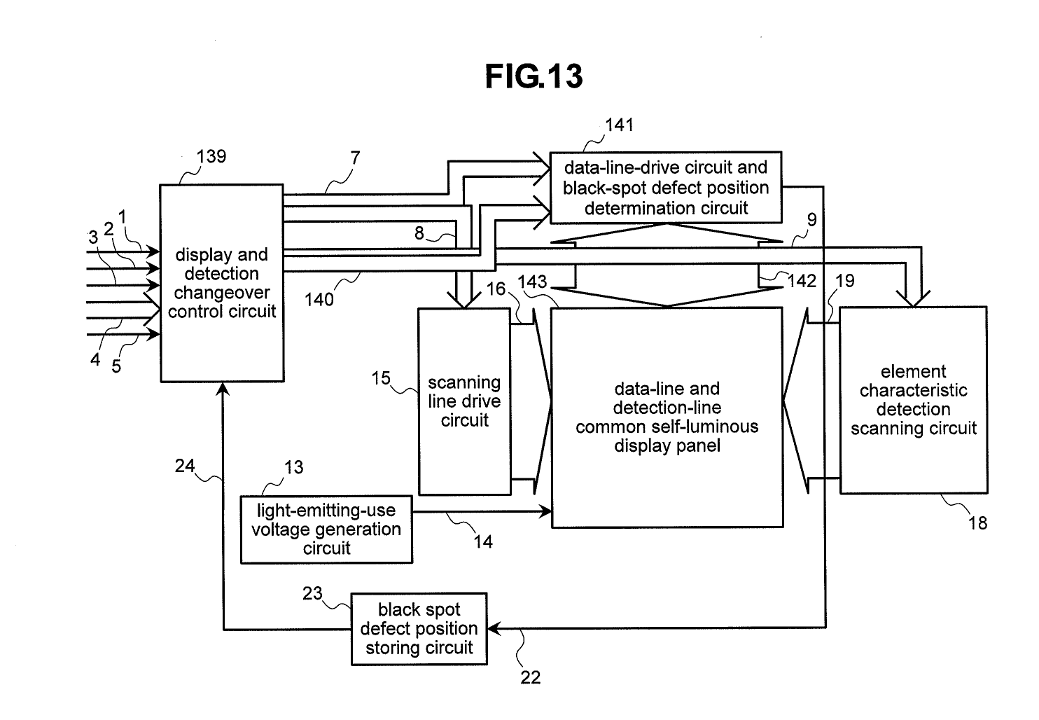

FIG. 13 is a schematic view of an image display device of this embodiment. In FIG. 13, parts to which the same symbols used in FIG. 1 are given have the substantially identical constitutions and perform the substantially identical operations. Numeral 139 indicates a display and detection changeover control circuit, numeral 140 indicates a display and detection changeover control signal, numeral 141 indicates a data-line-drive and black-spot defect position determination circuit, numeral 142 indicates a data-line drive and detection-line output signal, and numeral 143 indicates a data-line and detection-line common self-luminous display panel. The display and detection changeover control circuit 139 generates a data line control signal 7, a scanning line control signal 8 and a detection scanning line control signal 9 substantially equal to the corresponding signals used in the embodiment 1 and, at the same time, generates a display and detection changeover control signal 140 for changing over a data line drive operation and a detection operation. The data line drive circuit and black spot defect position determination circuit 141 has both of a function of the data line drive circuit and a function of the black spot defect position determination circuit in the embodiment 1, and supplies the data-line drive and detection-line output signal 142 to the data-line and detection-line common self-luminous display panel 143 via a common data line.

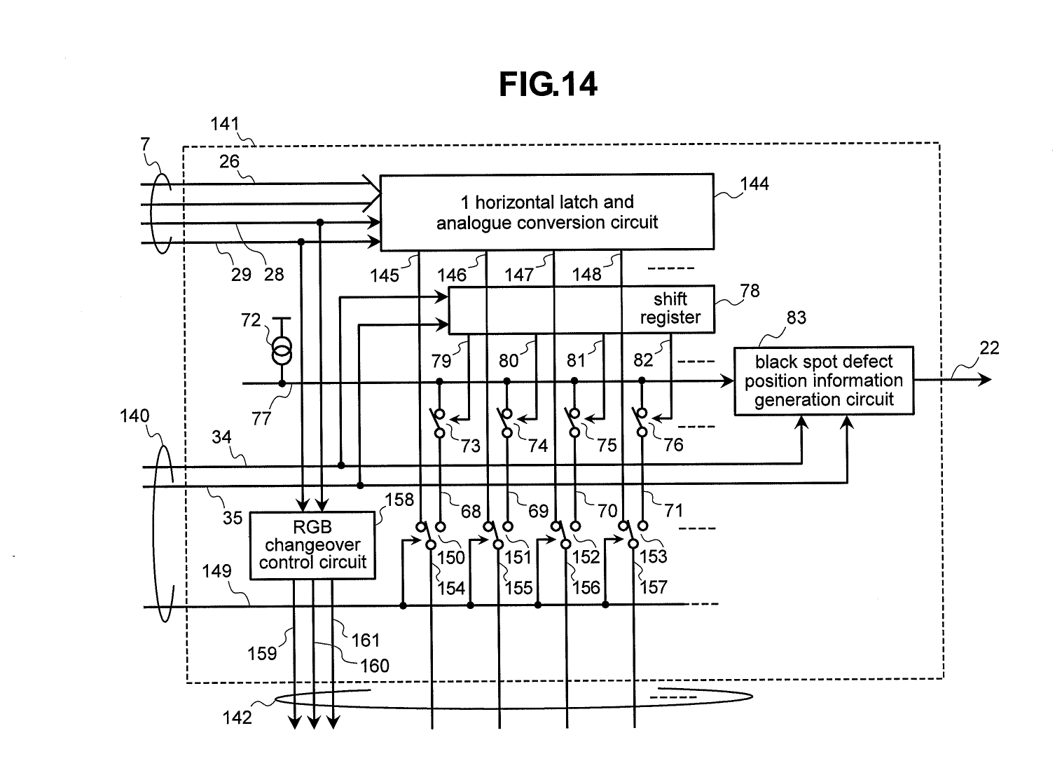

FIG. 14 is a view showing the internal constitution of the data-line-drive circuit and black spot defect position determination circuit 141 shown in FIG. 13. In FIG. 14, parts to which the same symbols used in FIG. 4 are given have the substantially identical constitutions and perform the substantially identical operations. Numeral 144 indicates a 1 horizontal latch and analog conversion circuit, numeral 145 indicates a first data line drive signal output, numeral 146 indicates a second data line drive signal output, numeral 147 indicates a third data line drive signal output, and numeral 148 indicates a fourth data line drive signal output. The 1 horizontal latch and analog conversion circuit 144, in the same manner as the embodiment 1, fetches the display correction data 26 to be inputted to the horizontal shift clock 29 using a horizontal start signal 28 as a head, and outputs data for 1 horizontal line as the first data line drive signal output 145, the second data line drive signal output 146, the third data line drive signal output 147, and the fourth data line drive signal output 148. Here, in the same manner as the embodiment 1, the following explanation is made with respect to a case in which the data line is outputted until the 240th data line drive signal is outputted.

Numeral 149 indicates a detection changeover signal, numeral 150 indicates a first data line detection changeover switch, numeral 151 indicates a second data line detection changeover switch, numeral 152 indicates a third data line detection changeover switch, numeral 153 indicates a fourth data line detection changeover switch, numeral 154 indicates a first data line and detection line, numeral 155 indicates a second data line and detection line, numeral 156 indicates a third data line and detection line, and numeral 157 indicates a fourth data line and detection line.

In the embodiment 2, different from the embodiment 1, the detection lines and the data lines are used in common and hence, the total number of lines becomes 240. The first data line detection changeover switch 150, the second data line detection changeover switch 151, the third data line detection changeover switch 152, the fourth data line detection changeover switch 153, . . . and the 240^{th} data line detection changeover switch, based on the detection changeover signal 149, at the time of performing the display driving output the first data line drive signal output 145, the second data line drive signal output 146, the third data line drive signal output 147, the fourth data line drive signal output 148, . . . , and 240^{th} data line drive signal output to the first data line and detection line 154, the second data line and detection line 155, the third data line and detection line 156, the fourth data line and detection line 157, . . . , and the 240^{th} data line and detection line thus performing an operation substantially equal to the display operation of the embodiment 1, while at the time of detection, connects the first detection line 68, the second detection line 69, the third detection line 70, the forth detection line 71, . . . , the 240^{th} detection line with the first data line and detection line 154, the second data line and detection line 155, the third data line and detection line 156, the fourth data line and detection line 157, . . . , and the 240^{th} data line and detection line thus performing the detection operation of the embodiment 1 within 1 horizontal period by dividing in accordance with R, G, B.

Numeral 158 indicates an RGB changeover control circuit, numeral 159 indicates an R display and detection selection signal, numeral 160 indicates a G display and detection selection signal, and numeral 161 indicates a B display and detection selection signal. The RGB changeover control circuit 158, in the same manner as the embodiment 1, performs writing of data line signals by dividing 1 horizontal period in three and, at the same time, at the time of detection, also generates an R display and detection selection signal 159, a G display and detection selection signal 160 and a B display and detection selection signal 161 which constitute changeover signals for dividing 1 horizontal period in three.

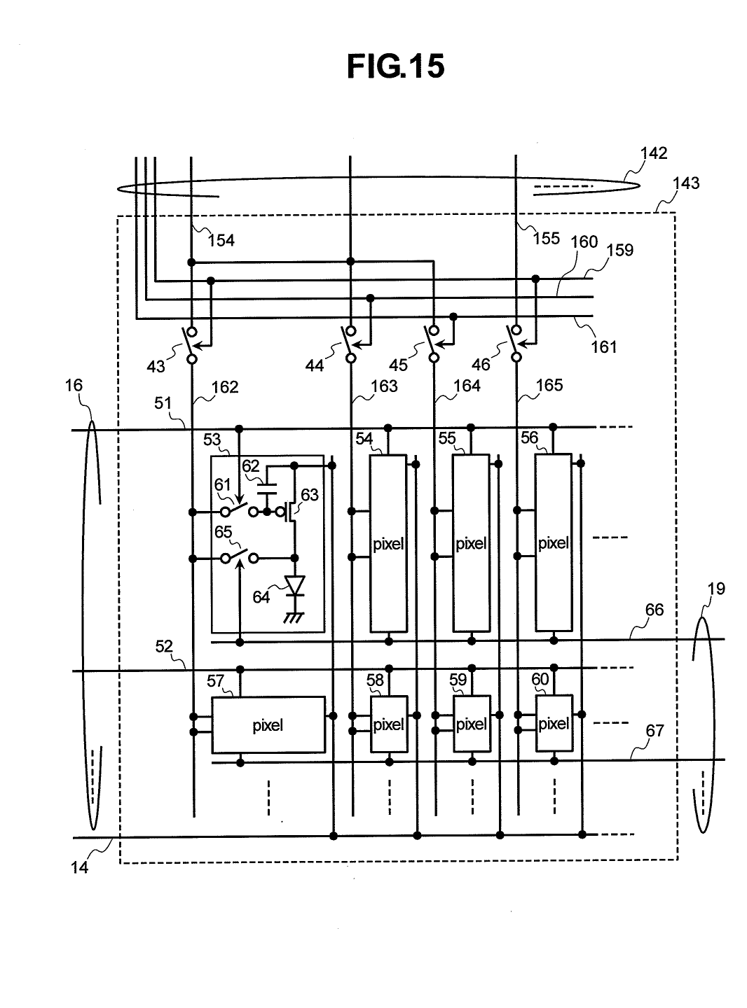

FIG. 15 is a view showing the internal constitution of the data line and detection line common self-luminous display panel 143 shown in FIG. 13. In FIG. 15, parts to which the same symbols used in FIG. 3 have the substantially identical constitutions and perform the substantially identical operations. Numeral 162 indicates a first R display detection common line, numeral 163 indicates a first G display detection common line, numeral 164 indicates a first B display detection common line, and numeral 165 indicates a second R display detection common line.

Here, the explanation is made with respect to a case in which 240 pieces of R display detection common lines, 240 pieces of G display detection common lines and 240 pieces of B display detection common lines respectively, that is, 720 pieces of display detection common lines in total are arranged in parallel to each other. The first R display detection common line 162, the first G display detection common line 163, the first B display detection common line 164, the second R display detection common line 165, . . . , 240th R display detection common line, the 240th G display detection common line, and the 240th B display detection common line are, at the time of performing display driving, respectively connected with the writing capacitance 62 by bringing the data writing switches 61 of the respective pixels into an ON state thus performing a signal voltage writing operation in the same manner as the embodiment 1 and, at the same time, at the time of detection, are connected with the organic EL 64 by bringing the detection switches 65 of the respective pixels into an ON state thus performing a characteristic detection operation in the same manner as the embodiment 1.

In this embodiment, the operations are performed in the same manner as the operations in the embodiment 1 except for the common use of the data lines and the detection lines which are used by changing over the lines.

What is claimed is:

1. An image display device capable of detecting a defect of a pixel: the image display device comprising:
a display panel which is constituted of a plurality of pixels;
a data line drive circuit which drives the pixels based on a data signal;
a control circuit which controls the data signal;
a detection line which detects a defective state of the pixel;
a defect position determination circuit which determines a defect position of the pixel based on an output signal from the detection line; and
a defect position storing circuit which stores the defect position from the defect position determination circuit and transmits the defect position to the control circuit, wherein
the defect position determination circuit includes a detection-use current source, a detection output line, a detection line switch and a defect position information generation circuit,
the detection-use current source is connected to the detection line via the detection output line and the detection line switch,
the detection output line is connected to an input terminal of the defect position information generation circuit, and
an output terminal of the defect position information generation circuit is connected to the defect position storing circuit.

2. An image display device according to claim 1, wherein the detection-use current source and the detection line are connected with each other during a period different from a display period within which the detection line switch outputs the data signal.

3. An image display device according to claim 1, wherein the defect position determination circuit determines the presence or the non-presence of the defects, and defect position storing circuit stores the presence or the non-presence of the defects for one screen.

4. An image display device according to claim 1, wherein the control circuit corrects data signals of pixels around a defective pixel and makes the defective pixel inconspicuous visually.

5. An image display device according to claim 1, wherein the display panel includes a selection switch which supplies signals of R(red), G(green), B(blue) by time division to the pixel as the data signals.

6. An image display device capable of detecting a defect of a pixel: the image display device comprising:
a display panel which is constituted of a plurality of pixels;
a data line drive circuit and a defect position determination circuit which drive the pixels based on a data signal and determines a defective state of the pixel; and
a control circuit which controls the data signal; and
a defect position storing circuit which stores a defect position acquired by the data line drive circuit and the defect position determination circuit and transmits the defect position to the control circuit, wherein
the data line drive circuit and the defect position determination circuit include a detection-use current source, a detection output line, a detection line switch, and a defect position information generation circuit,
the detection-use current source is connected with data lines and detection lines via the detection output line and the detection line switch,
the detection output line is connected to an input terminal of the defect position information generation circuit, and
an output terminal of the defect position information generation circuit is connected to the defect position storing circuit.

7. An image display device according to claim 6, wherein the detection-use current source, the data line and the detection line are connected with each other during a period different from a display period within which the detection line switch outputs the data signal.

8. An image display device according to claim 6, wherein the data line drive circuit and the defect position determination circuit determine the presence or the non-presence of the defects, and defect position storing circuit stores the presence or the non-presence of the defects for one screen.

9. An image display device according to claim 6, wherein the control circuit corrects data signals of pixels around a defective pixel and makes the defective pixel inconspicuous visually.

10. An image display device according to claim 6, wherein the display panel includes a selection switch which supplies signals of R(red), G(green), B(blue) by time division to the pixel as the data signals.

11. An image display device comprising:
a display panel which is constituted of a plurality of pixels;
a data line drive circuit which drives the pixels based on a data signal;
a scanning line drive circuit which scans the pixels;
a changeover circuit which changes over the connection of the pixels with the data line drive circuit or the connection of the pixels with a power source provided separately from a light emitting power source, and
a detection circuit which, when the pixel is connected with the power source provided separately from the light emitting power source, detects the pixel whose voltage is equal to or less than a threshold value.

12. An image display device according to claim 11, wherein the changeover circuit, during a period other than both of a period of supplying the data signal to the pixel and a light emission period of the pixel within 1 frame period, connects the pixel to a power source provided separately from the light emitting power source.

13. An image display device according to claim 11, wherein the image display device includes a correction circuit which corrects a data signal outputted to the pixel positioned around the pixel whose voltage is equal to or less than a threshold value.

14. An image display device comprising:
a display panel which is constituted of a plurality of pixels;
a data line drive circuit which drives the pixels based on a data signal;
a scanning line drive circuit which scans the pixels;
a changeover circuit which changes over the supply of a data signal to the pixels or the supply of electricity from a power source provided separately from a light emitting power source to the pixels, and
a detection circuit which, when electricity is supplied to the pixel from a power source provided separately from the light emitting power source, detects the pixel whose voltage is equal to or less than a threshold value.
